(19) United States
(12) Patent Application Publication
(10) Pub. No.: US 2010/0180820 A1
(43) Pub. Date: Jul. 22, 2010

(54) APPARATUS FOR TREATING POWDER

(76) Inventors: Hirokazu Ishimaru, Aichi (JP); Sreekumar Kurungot, Kerala (IN)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/668,708

(22) PCT Filed: Jul. 17, 2008
(86) PCT No.: PCT/JP2008/063329

§ 371 Date: Jan. 12, 2010

(30) Foreign Application Priority Data
Jul. 20, 2007 (JP) 2007-189301

(51) Int. Cl. C23C 16/00

(52) U.S. Cl. 118/723 R

(57) ABSTRACT

This invention provides an apparatus for treating powder that can enhance the efficiency of powder stirring by a simple mechanism and can uniformly coat all the powder surfaces with a metal catalyst and the like. The apparatus 10 for treating powder comprises at least: a chamber 11 for accommodating the powdery carbon support C, . . . comprising at least a bottom 11a, an endless upright wall 11b, and a plurality of skimming weirs 11c, . . . circumferentially provided on the inner peripheral surface of the upright wall 11b, provided that the chamber is rotatable around the vertical axis of the bottom 11a extended toward a given angle of inclination; an impact application means 15 for applying an impact to the chamber 11 at given time intervals; and an irradiation means (i.e., an arc plasma gun 3) for irradiating the inside of the chamber 11 with plasma.

### TECHNICAL FIELD

The present invention relates to an apparatus for treating powder and more particularly to a treatment apparatus used for supporting a metal catalyst on a powdery catalyst support for a fuel cell.

### BACKGROUND ART

Recently, hybrid cars and electric powered cars have drawn attention as environmentally friendly vehicles, and development aimed at further size reduction and more sophisticated performance thereof has been in progress day by day. In particular, fuel cells mounted within electric powered cars and the like are significantly different from internal combustion engines in terms of the principle of power generation, and fuel cells represent a form of in-vehicle equipment that plays a key roll in realization of for example, discharge of clean exhaust gas and quiet driving. However, it is no exaggeration to say that fuel cells are still under development, and it is imperative that product cost be reduced and performance be improved. Otherwise, it would be difficult to realize further deployment of electric powered cars.

Fuel cells involving the use of polyelectrolytes that function at relatively low temperatures use relatively expensive platinum for catalysts in positive and negative electrodes. The amounts of platinum used need to be decreased in order to reduce product cost, and high-performance electrodes need to be attained at the same time.

An example of a measure for attaining high-performance electrodes while reducing the amounts of platinum used is supporting platinum on the surface of a carbon particle support in a manner as uniform as possible. In order to uniformly support platinum on the support surface, for example, arc plasma processing could be carried out while effectively stirring powders. Examples of conventional techniques for realizing such effective stirring of powders include JP Patent Publication (kokai) Nos. 2004-250771 A and 2002-60943 A.

According to the technique disclosed in JP Patent Publication (kokai) No. 2004-250771 A, fine particles are accommodated in a polygonal barrel a, and the barrel a is rotated while stirring fine particles to form an adequate thin film on the surface thereof, as shown in FIG. 7. The technique disclosed in JP Patent Publication (kokai) No. 2002-60943 A concerns an apparatus for producing high-purity silicon-coated spheres. More particularly, such apparatus is equipped with a plurality of weirs in the direction of the inner circumference of a cylindrical chamber, and the chamber is allowed to rotate while accommodating spherical metals. This allows the spherical metals to be skimmed with weirs so as to lift the metals upward. The spherical metals are allowed to freely fall and are simultaneously subjected to plasma application, and a silicon coating is then provided on the metal sphere surfaces.

### DISCLOSURE OF THE INVENTION

The apparatus disclosed in JP Patent Publication (kokai) No. 2004-250771 A comprises a polygonal barrel, and such polygonal barrel allows fine particles to be stirred while colliding with each other at the corners of the barrel in response to rotation thereof. Thus, improved stirring performance can be expected, compared with a cylindrical barrel. Since the apparatus merely involves the use of a polygonal barrel, powders would not be actually stirred even if the barrel rotates, and large quantities of powders merely rotate as a single or a plurality of large masses, which is far from sufficient for stirring of powders.

The apparatus disclosed in JP Patent Publication (kokai) No. 2002-60943 A comprises a weir, which allows a spherical metal lifted to a high position in the chamber to freely fall, and repetition thereof can improve stirring performance. When target powders have relatively light weight, however, the powders disadvantageously adhere to the weir, and repetition of effective free fall cannot be expected. According to a measure in which stirring is intended only with the aid of rotation of the chamber, when the powder surfaces are to be subjected to plasma treatment, not all the treated powder surfaces would be assuredly oriented in the proper direction for plasma application. Thus, it is impossible to uniformly support a catalyst metal or the like on all the powder surfaces.

Under the above circumstances, the present invention is intended to provide an apparatus for treating powder that can enhance the efficiency of powder stirring using a simple mechanism and can uniformly coat all the powder surfaces with a metal catalyst and the like.

In order to attain the above object, the apparatus for treating powder of the present invention comprises at least: a chamber for accommodating powder comprising at least a bottom, an endless upright wall, and a plurality of skimming weirs circumferentially provided on the inner peripheral surface of the upright wall, provided that the chamber is rotatable around the vertical axis of the bottom extended toward a given angle of inclination; an impact application means for applying an impact to the chamber at given time intervals; and an irradiation means for irradiating the inside of the chamber with plasma.

The apparatus for treating powder of the present invention effectively breaks the target powder down to a minute size in its chamber and simultaneously subjects the surface of the minute powder to, for example, arc plasma irradiation to support a metal catalyst thereon. This apparatus is intended to overcome disadvantages, such as selective formation of a metal catalyst on a limited part of the aggregate due to powder aggregation, by breaking the powder down to a minute size at the time of plasma irradiation. This thus enlarges the effective area of the metal catalyst to uniformly support a metal catalyst on the surface of the minute powder.

Such apparatus comprises a chamber comprising a bottom, an endless upright wall, and a plurality of skimming weirs circumferentially provided on the inner peripheral surface of the upright wall. The chamber is allowed to rotate around an arbitrary axis while it is maintained at a certain inclined position relative to a horizontal plane. As a result of rotation of the chamber, powders are successively lifted upward by the skimming weir on the inner periphery surface. The lifted powders freely fail downward when the skimming weir reaches or passes through the apex.

When powder has a relatively light weight, however, the powder disadvantageously adheres to the skimming weir. When the strength of adherence surpasses the weight of the powder, free fall as expected cannot be realized.

Accordingly, the apparatus of the present invention is provided with an impact application means for applying an impact to the chamber at given time intervals, so as to effectively allow powder that has adhered to the skimming weir to freely fail. Such procedure is repeated to break the powder down to a minute size while preventing aggregation thereof in the chamber.

The powder broken down to a minute size in the chamber is subjected to plasma irradiation, so that a metal catalyst can be supported on the surface of fine powder in a manner as uniform as possible.

The angle of inclination of the chamber is preferably set at between approximately 30 and 60 degrees relative to the horizontal plane.

According to another embodiment of the present invention, the apparatus for treating powder comprises a surrounding body provided with a plurality of guide openings extended orthogonally with respect to the vertical axis on the outer periphery of the chamber. In the chamber, locking holes that extend in the opposite direction to the rotational direction are communicated with the ends of the guide openings, and weight members as the impact application means are accommodated in the guide openings. In response to rotation of the chamber and the surrounding body, the weight members in the locking holes move into the guide openings, and the weight members fall downward in the guide openings to apply an impact to the chamber at given time intervals.

According to an embodiment of the present invention, the apparatus involves the use of an weight member (e.g., an iron ball) of a given weight as an impact application means, and the weight member is allowed to freely fall in synchronization with rotation of the chamber to apply a certain level of impact to the chamber at given intervals. The structure (mechanism) thereof is very simple.

Locking holes for locking an weight member are allowed to communicate with the guide openings through which the weight member falls, and the locking holes extend in the opposite direction to the rotational direction of the chamber. This can automatically guide the weight member accommodated in the locking holes into the guide openings when, for example, the guide openings and the locking holes reach the apex, and the weight member is then allowed to freely fall so as to apply a certain level of impact to the chamber.

The weight member that has applied an impact to the chamber is guided into the guide opening, which has faced downward due to rotation of the chamber and the surrounding body, and the weight member is then automatically accommodated in the locking hole when it reaches the lowermost point.

Repetition of free fall and automatic lifting of the weight member described above enables impact application at constant intervals only via rotation of the chamber.

According to a preferable embodiment of the present invention, a plurality of protrusions that protrude into the chamber are provided at the bottom of the apparatus for treating powder of the present invention.

According to this embodiment, a plurality of protrusions are provided at the bottom of the chamber. By providing many protrusions at the bottom with which the powder that freely falls in the chamber first collide, powder stirring performance can further be enhanced. The specific configurations or dimensions of the protrusions are not particularly limited. For example, the protrusions may be prismatic, cylindrical, hemispherical, semielliptical, or endless ring units of different diameters.

The experimentation conducted by the present inventors has demonstrated as follows. When a plurality of protrusions are provided at the bottom of the chamber in the apparatus in which the chamber is inclined at 40 degrees relative to the horizontal plane, for example, the effective area of a platinum metal catalyst (i.e., an area per unit weight) is increased by approximately 10 times, compared with the apparatus without protrusions. This directly produces the effects such that platinum is more uniformly supported on the powder surface or the amount of platinum to be used can be reduced.

The apparatus for treating powder of the present invention may further comprise a control means that performs a pulse-controlled plasma irradiation by means of an irradiation means in synchronization with generation of an impact by the impact application means.

In order to realize effective arc plasma irradiation, pulse control is preferably carried out. When plasma irradiation is pulse-controlled, plasma irradiation in synchronization with generation of an impact applied to the chamber may be controlled. This enables plasma irradiation of powder immediately after breaking thereof down to a minute size and supporting of a metal catalyst in the most efficient and effective manner.

The apparatus for treating powder of the present invention is preferably used for treating, for example, the powder, which is a powdery carbon support, and a dry supporting of platinum or a platinum alloy on the carbon support. Since platinum is relatively expensive, the apparatus of the present invention may be used to enlarge the effective area per unit weight thereof, which can in turn reduce the amount of platinum to be used. Application of the apparatus of the present invention to such purposes is preferable for production of cell catalysts used for fuel cell vehicles, technological development of which is being in day-to-day progress and production of which is expanding in recent years. It is needless to say that such apparatus can be employed for production of a catalyst or the like used for diesel engines.

As is apparent from the foregoing description, the apparatus for treating powder of the present invention enables breaking of target powders down to a minute size without causing powder aggregation with a simple structure, and the apparatus enables uniform supporting of a metal catalyst on the powder surface. Since the effective area of the metal catalyst can be enlarged, the amount thereof to be used can also be reduced.

### BRIEF DESCRIPTION OF THE DRAWINGS

FIG. 1 is a lateral view of an embodiment of the apparatus for treating powder of the present invention.

FIG. 2 is a perspective view taken on the line II-II in FIG. 1.

FIG. 3 is an enlarged view of the chamber shown in FIG. 2.

FIG. 4 is an enlarged view of the chamber shown in FIG. 1.

FIG. 5(a) shows a TEM photograph of a catalyst supported with the use of a conventional apparatus and FIG. 5(b) shows a TEM photograph of a catalyst supported with the use of the apparatus of the present invention.

FIG. 6 shows the results of the experiment intended to verify the effects attained when a protrusion is provided at the bottom of the chamber; wherein (a) is a TEM photograph of a catalyst supported with the use of an apparatus having no protrusion at the bottom of the chamber; (b) is a TEM photograph of a catalyst supported with the use of an apparatus having a protrusion at the bottom of the chamber; and (c) is a chart showing a comparison of effective platinum areas of (a) and (b).

FIG. 7 shows a front view of a polygonal barrel constituting a conventional stirring apparatus.

In the figures, a numeral reference 1 indicates a rotating unit, a numeral reference 11 indicates a chamber, a numeral reference 11a indicates a bottom, a numeral reference 11b indicates a endless upright wall, a numeral reference 11c indicates a skimming weir, a numeral reference 11d indicates a protrusion, a numeral reference 12 indicates a surrounding body, a numeral reference 13 indicates a locking hole, a numeral reference 14 indicates a guide opening, a numeral reference 15 indicates a steel ball (an impact application means), a numeral reference 2 indicates a servomotor, a numeral reference 3 indicates an arc plasma gun, a numeral reference 4 indicates a vacuum pump, a numeral reference 5 indicates a rotary pump, a numeral reference 10 indicates an apparatus for treating powder, and reference C indicates a powdery carbon support.

### BEST MODES FOR CARRYING OUT THE INVENTION

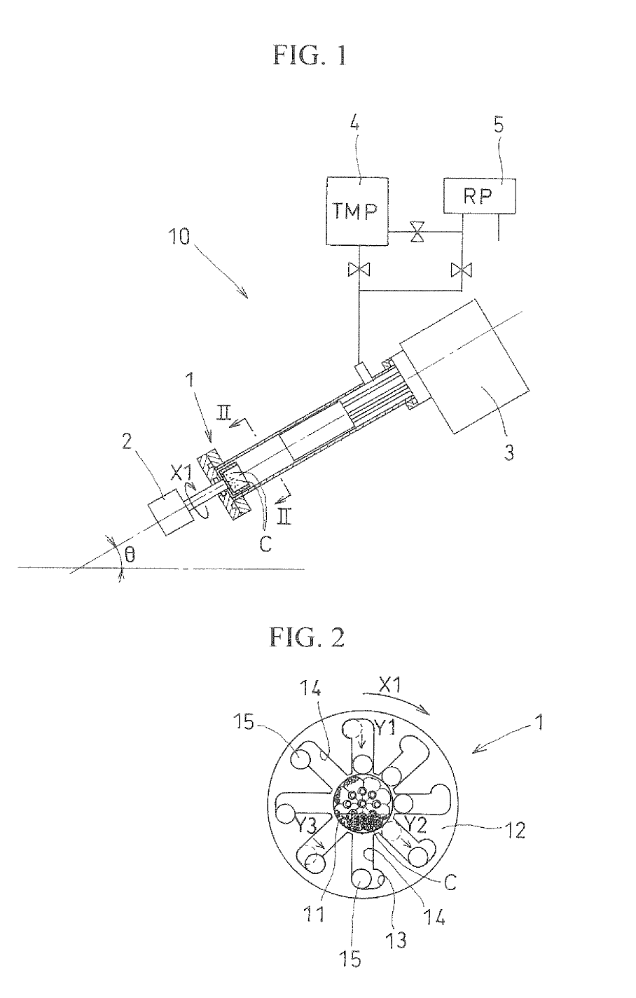

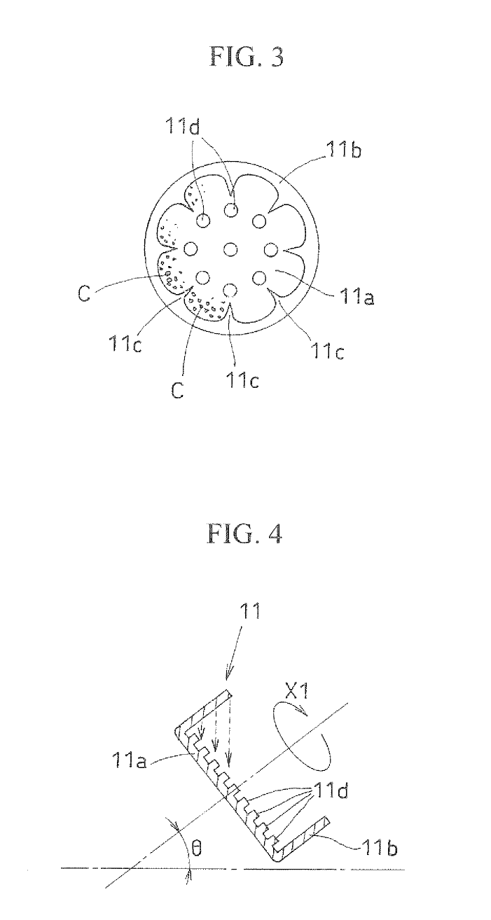

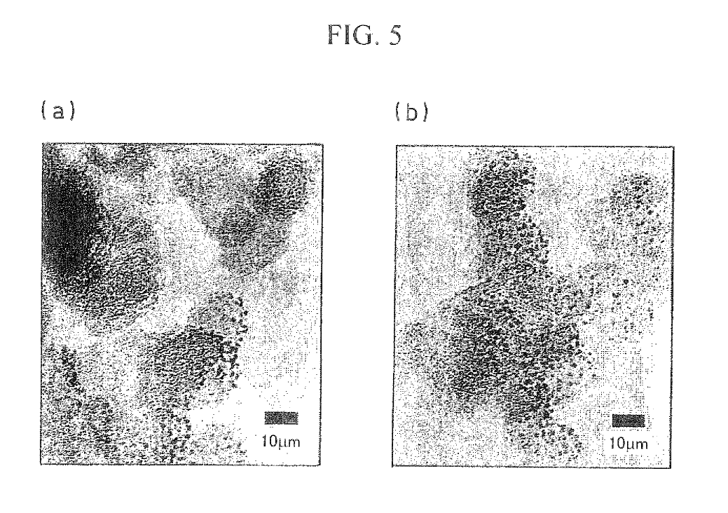

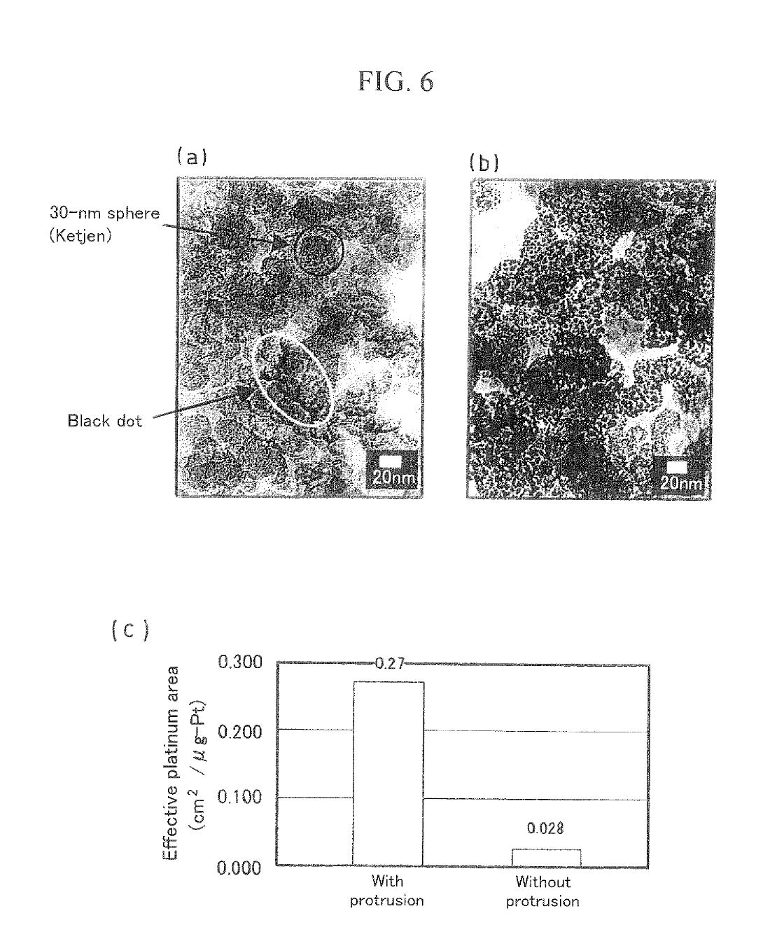

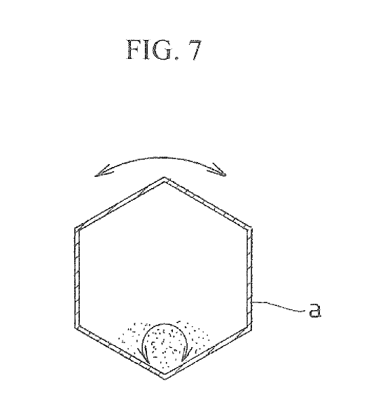

Hereafter, embodiments of the present invention are described with reference to the drawings. FIG. 1 is a lateral view of an embodiment of the apparatus for treating powder of the present invention, FIG. 2 is a perspective view taken on the line II-II in FIG. 1, FIG. 3 is an enlarged view of the chamber shown in FIG. 2, FIG. 4 is an enlarged view of the chamber shown in FIG. 1, FIG. 5(a) is a transmission electron microscopy (TEM) photograph of a catalyst supported with the use of a conventional apparatus, and FIG. 5(b) is a TEM photograph of a catalyst supported with the use of the apparatus of the present invention. FIG. 6 shows the results of the experiment intended to verify the effects attained when a protrusion is provided at the bottom of the chamber; wherein (a) is a TEM photograph of a catalyst supported with the use of an apparatus having no protrusion at the bottom of the chamber; (b) is a TEM photograph of a catalyst supported with the use of an apparatus having a protrusion at the bottom of the chamber; and (c) is a chart showing a comparison of effective platinum areas of (a) and (b).

### Examples

FIG. 1 schematically shows an embodiment of the apparatus for treating powder of the present invention. An arc plasma gun 3 is positioned and fixed to the apparatus 10 for treating powder in such a manner that the direction of plasma irradiation of the arc plasma gun 3 is inclined at θ degrees relative to the horizontal plane, a rotating unit 1 comprising a chamber that accommodates a powdery carbon support is mounted at the end of the direction of plasma irradiation, and the rotating unit 1 is rotatable at a given rate with the aid of a servomotor 2 located at the further end. The arc plasma gun 3 is communicated with the vacuum pump 4 (e.g., a turbo molecular pump; YTP150, ULVAC, Inc.) and with an auxiliary vacuum rotary pump 5. This enables evacuation of the gun, thereby discharging electricity.

The abovementioned direction of the angle θ is consistent with the rotational axis of the rotating unit 1. The range of the angle 8 is preferably set at between 30 degrees and 60 degrees, from the viewpoint of for example, acceleration of falling of a carbon support or steel ball and acceleration of collision of the fallen carbon support C, . . . with the protrusion at the bottom. Such angle is 40 degrees in this example.

FIG. 2 is a frontal view representing rotation of the rotation unit 1, taken on the line II-II in FIG. 1. The rotation unit 1 is constituted by a chamber 11 that accommodates a carbon support C, . . . located in the center of the rotation unit and a surrounding body 12 that surrounds the chamber 11. The chamber 11 is constituted by a disc-like bottom 11a, an endless upright wall 11b rising therefrom, a plurality of skimming weirs 11c provided in the peripheral direction of the upright wall 11b (8 weirs in the case of the example), . . . , and a plurality of protrusions 11d protruding into the chamber from the bottom 11a, as shown in FIG. 3, which is an enlarged view of the chamber 11, and in FIG. 4, which is a vertical cross-sectional view of the chamber 11.

The surrounding body 12 fixed on the outer periphery of the chamber 11 comprises a disc-like solid body and a plurality of guide openings 14, . . . therein (8 openings in the case of the example). The locking holes 13 that extend in the opposite direction to the rotational direction of the rotating unit 1 (the X1 direction shown in FIG. 2) are communicated with the ends of the guide openings 14, steel bails 15 are accommodated in the guide openings 14, and the steel balls 15 can be accommodated in the locking holes 13 and can reciprocally move into the guide openings 14 (i.e., it can freely fall and can be lifted).

With reference to FIG. 2, the steel balls 15 accommodated in the locking holes 13 move toward the guide openings 14 (i.e., the Y1 direction) in the guide openings 14 and locking holes 13 located at the apex of the rotating unit 1 in response to the rotation thereof toward the direction X1, the steel balls are guided into and freely fall in the guide openings 14, and the steel balls collide with the upright wall 11b of the chamber 11 to apply an impact to the chamber 11.

The steel balls 15 that have applied an impact to the chamber 11 by rotation of the rotating unit 1 freely move downward in the guide openings 14 (i.e., the Y2 direction). When the steel balls pass through the lowermost point of the guide openings 14 and turn upward, the steel balls are accommodated in the locking holes 13 again (i.e., the Y3 direction).

The eight steel balls 15, . . . repeat the abovementioned reciprocating movement within the corresponding guide openings 14 and the locking holes 13, during which the eight steel balls apply impacts to the chamber 11 at regular intervals.

The powdery carbon support C, . . . accommodated in the chamber 11 is skimmed by the skimming weir 11c on the inner peripheral surface of the chamber 11 in response to the rotation of the rotating unit 1, lifted upward, and slipped from the skimming weir at the apex or in the vicinity thereof. The carbon support then freely falls toward the bottom of the chamber.

Since the powdery carbon support C, . . . has light weight, it may adhere to the skimming weir 11c, and it is highly unlikely that it would satisfactorily undergo free fall.

The apparatus 10 for treating powder of the present invention causes the steel ball 15 to apply an impact to the chamber 11 at regular intervals. This results in separation of the powdery carbon support C, . . . that has adhered to the skimming weir 11c from the skimming weir 11c and satisfactory free fail in response to the rotation of the rotating unit 1.

As shown in FIG. 4, many protrusions 1 are provided at the bottom 11a in the chamber. Thus, the powdery carbon support C, . . . that has freely fallen first collides with the protrusions 11d, . . . , it becomes pulverized, it falls downward, it is skimmed by the skimming weir 11c, and it is then lifted upward. Also, the protrusions 11d, . . . are provided at the bottom 11a, and the powdery carbon support C, . . . is allowed to collide therewith. Thus, the carbon support surface that is oriented in the opposite direction to the direction of plasma irradiation can be changed as needed. This in turn results in uniform supporting of a metal catalyst on the carbon support surface.

With reference to FIG. 1 again, the apparatus 10 for treating powder is connected to a personal computer (not shown), and this computer can simultaneously transmit pulse signals to the plasma gun 3 and can apply plasma pulses. Also, the rotation speed of the servomotor 2 can be controlled by the computer, and the control unit that adjusts both the rotation speed and the timing of pulse signal transmission can apply plasma pulses in synchronization with impact application by means of the steel ball 15.

For example, arc plasma irradiation can be carried out with the degree of vacuum of 1×10⁻⁴ Pa, at ordinary temperature, at intervals of 1 pulse/sec, with the number of pulses of 1,000 times, and the number of servomotor rotation of 7.5 rpm.

The apparatus 10 for treating powder of the present invention enables the powdery carbon support to become powders of a minute unit without causing powder aggregation in the chamber, the resulting powders can be irradiated with arc plasma, and the platinum catalyst can then be supported uniformly on the carbon support surface.

[Analysis of TEM Photographs of Catalyst Supported with the Use of a Conventional Apparatus and with the Use of the Above Apparatus for Treating Powder]

The present inventors took TEM photographs of the catalysts supported with the use of a conventional apparatus involving stirring of the powdery carbon support within a cylindrical barrel and with the use of the above apparatus 10 for treating powder, and they compared the results. The results are shown in FIG. 5. FIG. 5a shows the case in which a conventional apparatus was used and FIG. 5b shows the case in which the apparatus of the present invention was used. In the photographs, a black dot represents a platinum catalyst and a light gray portion represents a carbon support.

As shown in FIG. 5a, platinum catalysts are concentrated in a certain area when a conventional apparatus is used. This clearly indicates that platinum is not uniformly supported on the carbon support surface.

As shown in FIG. 5b, carbon supports are dispersed at a more minute level, compared with those shown in FIG. 5a, when the apparatus of the present invention is used. Further, it can be more clearly visually observed that microparticles of platinum catalyst are uniformly supported on carbon support surfaces.

These results demonstrate that the use of the apparatus of the present invention enables microdispersion of carbon supports, and this in turn enables platinum particles to be uniformly supported on the microcarbon support surface.

### [Differences in Effective Platinum Area Depending on the Presence or Absence of Protrusions at the Bottom of the Chamber]

The present inventors conducted experiments in order to inspect the degrees of differences of the platinum area per unit weight caused by the presence or absence of protrusions at the bottom of the chamber. The apparatus 10 for treating powder and an apparatus that has the same constitution, with the exception that there was no protrusion at the bottom of the chamber, were used.

The TEM photographs after the treatment with the use of the apparatuses are shown in FIG. 6. FIG. 6a shows a case in which an apparatus without any protrusion was used, and FIG. 6b shows a case of an apparatus shown in the figure. As in the case of the above experimentation, a black dot in the figure represents platinum.

Comparison of FIG. 6a and FIG. 6b enables visual observation of microdispersion of carbon supports of the both cases. In the case of FIG. 6b, supporting of smaller platinum catalysts (i.e., with smaller particle diameters) can be visually observed on the surfaces.

The chart in FIG. 6c shows the results of measurement of the effective platinum areas by the rotating electrode method.

The figure indicates that an effective platinum area increases by approximately ten times when a protrusion is provided at the bottom of the chamber, compared with the case in which no protrusion is provided. This indicates that a reaction area per unit area can be increased or the amount of platinum to be used can be reduced.

The experiment demonstrates that it is important that a plurality of protrusions are provided at the bottom of the chamber, which can make the effects of the apparatus of the present invention to be more significant.

The embodiments of the present invention have been described in detail with reference to the drawings. It should be noted that concrete constitutions are not limited to these embodiments. The present invention is intended to include design modifications and the like within the scope of the present invention. For example, a powdery carbon support may be lifted by a belt conveyer mechanism and allowed to freely fall, instead of lifting of the powdery carbon support with the use of the rotating unit shown in the drawings, followed by free fall.

1. An apparatus for treating powder comprising at least:
a chamber for accommodating powder comprising at least a bottom, an endless upright wall, and a plurality of skimming weirs circumferentially provided on the inner peripheral surface of the upright wall, provided that the chamber is rotatable around the vertical axis of the bottom extended toward a given angle of inclination;
an impact application means for applying an impact to the chamber at given time intervals; and
an irradiation means for irradiating the inside of the chamber with plasma.

2. The apparatus for treating powder according to claim 1, which comprises a surrounding body provided with a plurality of guide openings extended orthogonally with respect to the vertical axis on the outer periphery of the chamber, wherein locking holes that extend in the opposite direction to the rotational direction are communicated with the ends of the guide openings, weight members as the impact application means are accommodated in the guide openings, and, in response to rotation of the chamber and the surrounding body, the weight members in the locking holes move into and fall in the guide openings, so as to apply an impact to the chamber at given time intervals.

3. The apparatus for treating powder according to claim 1, wherein the bottom comprises a plurality of protrusions protruding into the chamber.

4. The apparatus for treating powder according to claim 1, which further comprises a control means that performs a pulse-controlled plasma irradiation by means of an irradiation means in synchronization with generation of an impact by the impact application means.

5. The apparatus for treating powder according to claim 1, wherein the powder is a powdery carbon support and the apparatus is used to support platinum or a platinum alloy on the carbon support.
